(19) United States
(12) Patent Application Publication
(10) Pub. No.: US 2009/0046774 A1
(43) Pub. Date: Feb. 19, 2009

(54) SPACE-TIME CODING/DECODING METHOD FOR MULTI-ANTENNA PULSE TYPE COMMUNICATION SYSTEM

(75) Inventor: Chadi ABOU RJEILY, Byblor (LB)

Correspondence Address: Nixon Peabody LLP, 200 Page Mill Road, Palo Alto, CA, 94306, US

(73) Assignee: COMMISSARIAT A L'ENERGIE ATOMIQUE, Paris (FR)

(21) Appl. No.: 12/192,048

(22) Filed: Aug. 14, 2008

(30) Foreign Application Priority Data
Aug. 16, 2007 (FR) 07 57079

(51) Int. Cl. H03K 9/04

(52) U.S. Cl. 375/239

(57) ABSTRACT

A space-time coding method for a UWB pulse type transmission/reception system. The space-time code, given for P=2, 4 or 8 transmission antennas, makes it possible to code 2-PPM information symbols and to modulate the position of UWB pulse signals using coded symbols, without requiring extension of the modulation alphabet. The space-time code is real with maximum diversity, and is full speed. The space-time decoding method is capable of estimating the information symbols thus transmitted.

### CROSS REFERENCE TO RELATED APPLICATIONS OR PRIORITY CLAIM

This application claims priority to French Patent Application No. 07 57079, filed Aug. 16, 2007.

### DESCRIPTION

1. Technical Domain

The present invention relates to the domain of Ultra Wide Band UWB telecommunications as well as the domain of multi-antenna Space Time Coding STC systems.

2. State of Prior Art

Wireless telecommunication systems of the multi-antenna type are well known in the state of the art. These systems use a plurality of emission and/or reception antennas and, depending on the adopted configuration type, are referred to as MIMO (Multiple Input Multiple Output), MISO (Multiple Input Single Output) or SIMO (Single Input Multiple Output). We will subsequently use this term MIMO to cover the above-mentioned MIMO and MISO variants. The use of spatial diversity in emission and/or in reception enables these systems to offer much higher channel capacities than classical single-antenna systems (SISO for Single Input Single Output). This spatial diversity is usually complemented with time diversity by means of space-time coding. In such coding, an information symbol to be transmitted is coded on several antennas and at several transmission instants. Two main categories of MIMO systems with space-time coding are known, firstly Space Time Trellis Coding (STTC) systems and Space Time Block Coding (STBC) systems. In a trellis coding system, the space-time coder may be seen as a finite states machine supplying P transmission symbols to P antennas as a function of the current state and the information symbol to be coded. Decoding on reception is done by a multi-dimensional Viterbi algorithm for which the complexity increases exponentially as a function of the number of states. In a block coding system, an information symbol block to be transmitted is coded in a transmission symbol matrix, one dimension of the matrix corresponding to the number of antennas and the other corresponding to consecutive transmission instants.

FIG. 1 diagrammatically shows a MIMO transmission system 100 with STBC coding. An information symbol block S=(σ₁, . . . , σ_{b}), for example a binary word with b bits or more generally b M-ary symbols, is coded as a space-time matrix:

$$C = ( \begin{matrix}{c}_{1 , 1} & {c}_{1 , 2} & … & {c}_{1 , P} \\ {c}_{2 , 1} & {c}_{2 , 2} & … & {c}_{2 , P} \\ ⋮ & ⋮ & ⋰ & ⋮ \\ {c}_{T , 1} & {c}_{T , 2} & … & {c}_{T , P}\end{matrix} ) \qquad ( 1 )$$

in which the coefficients c_{t,p}, t=1, . . . , T; p=1, . . . , P of the code are usually complex coefficients depending on information symbols, P is the number of antennas used for the emission, T is an integer number indicating the time extension of the code, in other words the number of channel uses or PCUs (Per Channel Use).

The function ƒ that makes the space-time code word C correspond to any information symbol vector S is called the coding function. If the function ƒ is linear, it is said that the space-time code is linear. If the coefficients c_{t,p} are real, the space-time code is said to be real.

In FIG. 1, a space-time coder is denoted by 110. At each usage instant of the channel t, the encoder provides the multiplexer 120 with the t-th row vector of the matrix C. The multiplexer transmits the coefficients of the row vector to the modulators 130₁, . . . , 130_{P} and the modulated signals are transmitted by the antennas 140₁, . . . , 140_{P}.

The space-time code is characterized by its rate, in other words by the number of information symbols that it transmits per channel use (PCU). The code is said to be full rate if it is P times higher than the rate for a single antenna use (SISO).

The space-time code is also characterized by its diversity that can be defined as the rank of the matrix C. There will be a maximum diversity if the matrix C₁-C₂ is full rank for two arbitrary code words C₁ and C₂ corresponding to two vectors S₁ and S₂.

Finally, the space-time code is characterized by its coding gain that reflects the minimum distance between different code words. It can be defined as follows:

$${min}_{{C}_{1} \neq {C}_{2}} det ( {( {C}_{1} - {C}_{2} )}^{H} ( {C}_{1} - {C}_{2} ) ) \qquad ( 2 )$$

where, equivalently, for a linear code:

$${min}_{C \neq 0} det ( {C}^{H} C ) \qquad ( 3 )$$

where det(C) refers to the determinant of C and C^{H} is the conjugate transpose matrix of C. The code gain for a given transmission energy per information symbol, is limited.

A space-time code will be particularly resistant to fading if its coding gain is high.

One of the first examples of space-time coding for a MIMO system with two transmission antennas was proposed in the article by S. M. Alamouti entitled <<A transmit diversity technique for wireless communications>>, published in the IEEE Journal on selected areas in communications, vol. 16, pp. 1451-1458, October 1998. The Alamouti code is defined by the 2×2 space-time matrix:

$$C = ( \begin{matrix}{σ}_{1} & {σ}_{2} \\ - {σ}_{2}^{*} & {σ}_{1}^{*}\end{matrix} ) \qquad ( 4 )$$

where σ₁ and σ₂ are two information symbols to be transmitted and σ*₁ and σ*₂ are their corresponding conjugates. As can be seen in the expression (4), this code transmits two information symbols for two uses of the channel and therefore its speed is one symbot/PCU.

Although initially presented in the above-mentioned article for symbols belonging to a QAM modulation, the Alamouti code is also applicable to information symbols belonging to a PAM or PSK modulation. However, it cannot easily be extended to a position modulation PPM (Pulse Position Modulation). The symbol for a PPM modulation alphabet with M positions may be represented by a vector of M components all of which are null except for one equal to “1”, corresponding to the modulation position at which a pulse is emitted. The use of PPM symbols in expression (4) then leads to a space-time matrix with size 2M×2. The term −σ*₂ appearing in the matrix is not a PPM symbol in the alphabet. It involves the transmission of a pulse affected by a sign change. In other words, this is equivalent to using PPM symbols belonging to an extension of the PPM modulation alphabet.

More generally, the use of PPM symbols in space-time codes, particularly real orthogonal codes defined by V. Tarokh et al. in the article entitled <<Space-time block codes from orthogonal designs>> published in IEEE Trans. on Infornation Theory, Vol. 45, No. 5, July 1999, pp. 1456-1567, leads to an extension of the PPM modulation alphabet.

The real orthogonal codes introduced in this article may be considered as a generalisation of the Alamouti code when the information symbols are real. However, these codes only exist for P=2, 4, 8 transmission antennas. More precisely:

$$for P = 2 , C = ( \begin{matrix}{σ}_{1} & {σ}_{2} \\ - {σ}_{2} & {σ}_{1}\end{matrix} ) \\ for P = 4 , C = ( \begin{matrix}{σ}_{1} & {σ}_{2} & {σ}_{3} & {σ}_{4} \\ - {σ}_{2} & {σ}_{1} & - {σ}_{4} & {σ}_{3} \\ - {σ}_{3} & {σ}_{4} & {σ}_{1} & - {σ}_{2} \\ - {σ}_{4} & - {σ}_{3} & {σ}_{2} & {σ}_{1}\end{matrix} ) \\ and for P = 8 , \\ C = ( \begin{matrix}{σ}_{1} & {σ}_{2} & {σ}_{3} & {σ}_{4} & {σ}_{5} & {σ}_{6} & {σ}_{7} & {σ}_{8} \\ - {σ}_{2} & {σ}_{1} & {σ}_{4} & - {σ}_{3} & {σ}_{6} & - {σ}_{5} & - {σ}_{8} & {σ}_{7} \\ - {σ}_{3} & - {σ}_{4} & {σ}_{1} & {σ}_{2} & {σ}_{7} & {σ}_{8} & - {σ}_{5} & - {σ}_{6} \\ - {σ}_{4} & {σ}_{3} & - {σ}_{2} & {σ}_{1} & {σ}_{8} & - {σ}_{7} & {σ}_{6} & - {σ}_{5} \\ - {σ}_{5} & - {σ}_{6} & - {σ}_{7} & - {σ}_{8} & {σ}_{1} & {σ}_{2} & {σ}_{3} & {σ}_{4} \\ - {σ}_{6} & {σ}_{5} & - {σ}_{8} & {σ}_{7} & - {σ}_{2} & {σ}_{1} & - {σ}_{4} & {σ}_{3} \\ - {σ}_{7} & {σ}_{8} & {σ}_{5} & - {σ}_{6} & - {σ}_{3} & {σ}_{4} & {σ}_{1} & - {σ}_{2} \\ - {σ}_{8} & - {σ}_{7} & {σ}_{6} & {σ}_{5} & - {σ}_{4} & - {σ}_{3} & {σ}_{2} & {σ}_{1}\end{matrix} ) \qquad ( 5 )$$

where σₚ, p=1, . . . , 8 are real information symbols, for example PAM symbols. As for the Alamouti code, it can be seen that the only way to use PPM symbols is to introduce signed pulses, which is equivalent to using an extended PPM alphabet in which elements would be vectors with M components, all of which are zero except for one equal to ±1.

Considerable research is now being carried out on another telecommunications domain, namely UWB telecommunication systems that are particularly promising for the development of future wireless personal networks (WPAN). These systems are specific in that they can work directly in base band with very wide band signals. A UWB signal usually means a signal conforming with the spectral mask stipulated in the FCC Feb. 14, 2002 regulations revised March 2005, in other words essentially a signal in the spectral band 3.1 at 10.6 GHz and with a band width of at least 500 MHz at −10 dB. In practice, two types of UWB signals are known, multi-band OFDM (MB-OFDM) signals and UWB pulse type signals. We will be interested only in UWB pulse type signals in the following description.

A UWB pulse signal is composed of very short pulses, typically of the order of a few hundred picoseconds distributed within a frame. A distinct Time Hopping (TH) code is assigned to each user, to reduce Multi-Access Interference (MAI). The output signal or the signal addressed to a user k can then be written as follows:

$${s}_{k} ( t ) = {\sum }_{n = 0}^{{N}_{s} - 1} w ( t - {nT}_{s} - {c}_{k} ( n ) {T}_{c} ) \qquad ( 6 )$$

where w is the form of the elementary pulse, T_{c} is a chip duration, Tₛ is the duration of an elementary interval with Nₛ=N_{c}T_{c}, where N_{c} is the number of chips in an interval, the total frame duration being T_{ƒ}=NₛTₛ where Nₛ is the number of intervals in the frame. The duration of the elementary pulse is chosen to be less than the chip duration, namely T_{w}≦T_{c}. The sequence cₖ(n) for n=0, . . . , Nₛ−1 defines the time hopping code of the user k. Time hopping sequences are chosen to minimize the number of collisions between pulses belonging to time hopping sequences of different users.

FIG. 2A shows a TH-UWB signal associated with a user k. Usually the TH-UWB signal is modulated by means of a position modulation so as to transmit a given information symbol from or to a user k, namely for the modulated signal:

$${s}_{k} ( t ) = {\sum }_{n = 0}^{{N}_{s} - 1} w ( t - {nT}_{s} - {c}_{k} ( n ) {T}_{c} - {μ}_{k} ɛ ) \qquad ( 7 )$$

where ε is a dither significantly less than the chip duration and μₖ ε{0, . . . , M−1} is the M-ary PPM position of the symbol, the first position being considered in this description as introducing a zero delay.

Instead of separating different users by means of time hopping codes, it is also possible to separate them by orthogonal codes, for example Hadamard codes as in DS-CDMA. We then refer to DS-UWB (Direct Spread UWB). In this case, we obtain the following expression for the unmodulated signal corresponding to (6):

$${s}_{k} ( t ) = {\sum }_{n = 0}^{{N}_{s} - 1} {b}_{n}^{( k )} w ( t - {nT}_{s} ) \qquad ( 8 )$$

where bₙ^{(k)}, n=0, . . . , Nₛ−1 is the spreading sequence for the user k. Note that the expression (8) is similar to the expression of a conventional DS-CDMA signal. However, it differs therefrom in that the chips do not occupy the entire frame, but are distributed at period Tₛ. FIG. 2B shows a DS-UWB signal associated with a user k.

As above, the information symbols can be transmitted using a PPM modulation. The DS-UWB signal modulated in position corresponding to the TH-UWB (7) signal may be expressed as follows, using the same notations:

$${s}_{k} ( t ) = {\sum }_{n = 0}^{{N}_{s} - 1} {b}_{n}^{( k )} \cdot w ( t - {nT}_{s} - {μ}_{k} ɛ ) \qquad ( 9 )$$

Finally, it is known that time hopping codes and spectral spreading codes can be combined to provide multiple access to different users. The result is then a UWB pulse signal TH-DS-UWB with the general form:

$${s}_{k} ( t ) = {\sum }_{n = 0}^{{N}_{s} - 1} {b}_{n}^{( k )} \cdot w ( t - {nT}_{s} - {c}_{k} ( n ) {T}_{c} ) \qquad ( 10 )$$

FIG. 2C shows a TH-DS-UWB signal associated with a user k. This signal may be modulated by a position modulation. The result is then the following for the modulated signal:

$${s}_{k} ( t ) = {\sum }_{n = 0}^{{N}_{s} - 1} {b}_{n}^{( k )} \cdot w ( t - {nT}_{s} - {c}_{k} ( n ) {T}_{c} - {μ}_{k} ɛ ) \qquad ( 11 )$$

It is known in the state-of-the-art that UWB signals can be used in MIMO systems. In this case, each antenna transmits a UWB signal modulated as a function of an information symbol or a block of such symbols (STBC). However, as has been seen above, the use of PPM information symbols in space-time codes requires the use of signed pulses, in other words the use of a 2-PAM-M-PPM extended modulation alphabet. Taking account of the phase inversion also requires an RF architecture in emission and in reception that is more complex than that used for a conventional impulse system. Finally, some UWB systems cannot be used at all or only with difficulty for the transmission of signed pulses. For example, optical UWB systems only transmit signals with light intensity TH-UWB, necessarily without any sign information.

The purpose of this invention is to propose a particularly simple and robust space-time coding method for a multi-antenna UWB system. While using a position modulation, the coding method according to this invention does not require extension to the modulation alphabet. In particular, it means that there is no need to use signed pulse transmission when the modulation support signal is of the TH-UWB type.

A second purpose of this invention is to propose a decoding method for estimating symbols transmitted according to the above method.

### PRESENTATION OF THE INVENTION

This invention is defined by a space-time coding method for a UWB transmission system comprising a plurality P of radiating elements where P=2, 4 or 8, said method coding a block of information symbols S=(σ₁, σ₂, . . . , σ_{P}) belonging to a 2-PPM modulation alphabet into a sequence of vectors, the components of a vector being intended to modulate the position of a UWB pulse signal for a given radiating element of said system and use of given transmission channels, each component corresponding to a PPM modulation position. Said vectors are obtained from elements of the matrix:

$$C = ( \begin{matrix}{σ}_{1} & {σ}_{2} \\ Ω {σ}_{2} & {σ}_{1}\end{matrix} ) for P = 2 , \\ C = ( \begin{matrix}{σ}_{1} & {σ}_{2} & {σ}_{3} & {σ}_{4} \\ Ω {σ}_{2} & {σ}_{1} & Ω {σ}_{4} & {σ}_{3} \\ Ω {σ}_{3} & {σ}_{4} & {σ}_{1} & Ω {σ}_{2} \\ Ω {σ}_{4} & Ω {σ}_{3} & {σ}_{2} & {σ}_{1}\end{matrix} ) for P = 4 , \\ C = ( \begin{matrix}{σ}_{1} & {σ}_{2} & {σ}_{3} & {σ}_{4} & {σ}_{5} & {σ}_{6} & {σ}_{7} & {σ}_{8} \\ Ω {σ}_{2} & {σ}_{1} & {σ}_{4} & Ω {σ}_{3} & {σ}_{6} & Ω {σ}_{5} & Ω {σ}_{8} & {σ}_{7} \\ Ω {σ}_{3} & Ω {σ}_{4} & {σ}_{1} & {σ}_{2} & {σ}_{7} & {σ}_{8} & Ω {σ}_{5} & Ω {σ}_{6} \\ Ω {σ}_{4} & {σ}_{3} & Ω {σ}_{2} & {σ}_{1} & {σ}_{8} & Ω {σ}_{7} & {σ}_{6} & Ω {σ}_{5} \\ Ω {σ}_{5} & Ω {σ}_{6} & Ω {σ}_{7} & Ω {σ}_{8} & {σ}_{1} & {σ}_{2} & {σ}_{3} & {σ}_{4} \\ Ω {σ}_{6} & {σ}_{5} & Ω {σ}_{8} & {σ}_{7} & Ω {σ}_{2} & {σ}_{1} & Ω {σ}_{4} & {σ}_{3} \\ Ω {σ}_{7} & {σ}_{8} & {σ}_{5} & Ω {σ}_{6} & Ω {σ}_{3} & {σ}_{4} & {σ}_{1} & Ω {σ}_{2} \\ Ω {σ}_{8} & Ω {σ}_{7} & {σ}_{6} & {σ}_{5} & Ω {σ}_{4} & Ω {σ}_{3} & {σ}_{2} & {σ}_{1}\end{matrix} ) for P = 8 ,$$

each row in the matrix corresponding to one use of the transmission channel and each column of the matrix corresponding to a radiating element, the matrix C being defined except for a permutation of its rows and/or columns and Ω being a permutation of the two PPM modulation positions.

According to a first variant, said pulse signal is a TH-UWB signal.

According to a second variant, said pulse signal is a DS-UWB signal.

According to a third variant, said pulse signal is a TH-DS-UWB signal.

The invention also relates to a UWB transmission system comprising a plurality P of radiating elements, where P=2, 4 or 8, comprising:

coding means to code a block of information symbols S=(σ₁, σ₂, . . . , σ_{P}) belonging to a 2-PPM modulation alphabet into a sequence of vectors, each vector being associated with a given use of the transmission channel and a given radiating element, each component of a vector corresponding to a PPM modulation position, said vectors being obtained from elements of the matrix

$$C = ( \begin{matrix}{σ}_{1} & {σ}_{2} \\ Ω {σ}_{2} & {σ}_{1}\end{matrix} ) for P = 2 , \\ C = ( \begin{matrix}{σ}_{1} & {σ}_{2} & {σ}_{3} & {σ}_{4} \\ Ω {σ}_{2} & {σ}_{1} & Ω {σ}_{4} & {σ}_{3} \\ Ω {σ}_{3} & {σ}_{4} & {σ}_{1} & Ω {σ}_{2} \\ Ω {σ}_{4} & Ω {σ}_{3} & {σ}_{2} & {σ}_{1}\end{matrix} ) for P = 4 , \\ C = ( \begin{matrix}{σ}_{1} & {σ}_{2} & {σ}_{3} & {σ}_{4} & {σ}_{5} & {σ}_{6} & {σ}_{7} & {σ}_{8} \\ Ω {σ}_{2} & {σ}_{1} & {σ}_{4} & Ω {σ}_{3} & {σ}_{6} & Ω {σ}_{5} & Ω {σ}_{8} & {σ}_{7} \\ Ω {σ}_{3} & Ω {σ}_{4} & {σ}_{1} & {σ}_{2} & {σ}_{7} & {σ}_{8} & Ω {σ}_{5} & Ω {σ}_{6} \\ Ω {σ}_{4} & {σ}_{3} & Ω {σ}_{2} & {σ}_{1} & {σ}_{8} & Ω {σ}_{7} & {σ}_{6} & Ω {σ}_{5} \\ Ω {σ}_{5} & Ω {σ}_{6} & Ω {σ}_{7} & Ω {σ}_{8} & {σ}_{1} & {σ}_{2} & {σ}_{3} & {σ}_{4} \\ Ω {σ}_{6} & {σ}_{5} & Ω {σ}_{8} & {σ}_{7} & Ω {σ}_{2} & {σ}_{1} & Ω {σ}_{4} & {σ}_{3} \\ Ω {σ}_{7} & {σ}_{8} & {σ}_{5} & {σ}_{6} & Ω {σ}_{3} & {σ}_{4} & {σ}_{1} & Ω {σ}_{2} \\ Ω {σ}_{8} & Ω {σ}_{7} & {σ}_{6} & {σ}_{5} & Ω {σ}_{4} & Ω {σ}_{3} & {σ}_{2} & {σ}_{1}\end{matrix} )$$

$$for P = 8 ,$$

one row of the matrix corresponding to one use of the transmission channel and one column of the matrix corresponding to one radiating element, the matrix C being defined within one permutation of its rows and/or columns and Ω being a permutation of the two PPM modulation positions;

a plurality of modulators to modulate the position of a UWB pulse signal, each modulator being associated with a radiating element and modulating the position of said signal during use of the transmission channel, by means of the components of the vector associated with said radiating element and said use of the channel;

each radiating element being adapted to emit the signal thus modulated by said associated modulator.

According to a first embodiment, the radiating elements are UWB antennas.

According to a second embodiment, the radiating elements are laser diodes or light emitting diodes.

The invention also relates to a space-time decoding method for a UWB reception system with Q sensors, designed to estimate information symbols transmitted by the transmission system defined above, the method comprising:

a step to obtain 2QL decision variables associated with 2QL reception channels, each reception channel being related to a sensor, a propagation path between the transmission and reception systems, and a modulation position of the 2-PPM modulation alphabet, said obtaining step being repeated for P consecutive uses of the transmission channel, to provide a vector Y with size 2QLP, for which the components are the 2QL decision variables obtained for said P uses;

a step to calculate the vector Z=Y−(I_{P}\textcircled{×}H)Γ where I_{P} is the unit matrix with size P×P, H is the matrix representative of the transmission channel, Γ is a constant vector representative of the code and \textcircled{×} is the Kronecker product;

a step to calculate the \tilde{Z}=(h_{φ}^{H}\textcircled{×}I₂)Z vector, where h_{φ}=(I_{P}\textcircled{×}h)φ, and where I₂ is the unit matrix with size 2×2, h is a reduced channel matrix such that H=h\textcircled{×}I₂ and φ is the matrix

$$ϕ = ( \begin{matrix}1 & 0 \\ 0 & - 1 \\ 0 & 1 \\ 1 & 0\end{matrix} ) for P = 2 , \\ ϕ = ( \begin{matrix}1 & 0 & 0 & 0 \\ 0 & - 1 & 0 & 0 \\ 0 & 0 & 0 & 0 \\ 0 & 0 & 0 & - 1 \\ 0 & 1 & 0 & 0 \\ 1 & 0 & 0 & 0 \\ 0 & 0 & 0 & 1 \\ 0 & 0 & - 1 & 0 \\ 0 & 0 & 1 & 0 \\ 0 & 0 & 0 & - 1 \\ 1 & 0 & 0 & 0 \\ 0 & 1 & 0 & 0 \\ 0 & 0 & 0 & 1 \\ 0 & 0 & 1 & 0 \\ 0 & - 1 & 0 & 0 \\ 1 & 0 & 0 & 0\end{matrix} ) , for P = 4$$

and the matrix in the appendix for P=8;

a step, to compare the components of the vector \tilde{Z} applicable to the two PPM positions of each symbol, the estimated PPM position being the position corresponding to the largest amplitude component.

Finally, the invention relates to a UWB reception system comprising a plurality Q of sensors and for each sensor, an associated Rake receiver, characterised in that each Rake receiver comprises a plurality 2 L of fingers, each finger corresponding to a propagation path and to a modulation position of the 2-PPM modulation alphabet, the system also comprising:

serial to parallel conversion means to form a vector Y with size 2QLP, for which the components are the 2QL outputs from the Rake receiver fingers, for P consecutive uses of the transmission channel;

calculation means, firstly to calculate a vector Z=Y−(I_{P}\textcircled{×}H)Γ where I_{P} is the unit matrix with size P×P, H is a matrix representative of the transmission channel, Γ is a constant vector representative of the code and \textcircled{×} is the Kronecker product, then a vector \tilde{Z}=(h_{φ}^{H}\textcircled{×}I₂)Z where h_{φ}=(I_{P}\textcircled{×}h)φ, and where I₂ is the unit matrix with size 2×2, h is a reduced channel matrix such that H=h\textcircled{×}I₂ and φ is the matrix:

$$ϕ = ( \begin{matrix}1 & 0 \\ 0 & - 1 \\ 0 & 1 \\ 1 & 0\end{matrix} ) for , P = 2$$

$$ϕ = ( \begin{matrix}1 & 0 & 0 & 0 \\ 0 & - 1 & 0 & 0 \\ 0 & 0 & 0 & 0 \\ 0 & 0 & 0 & - 1 \\ 0 & 1 & 0 & 0 \\ 1 & 0 & 0 & 0 \\ 0 & 0 & 0 & 1 \\ 0 & 0 & - 1 & 0 \\ 0 & 0 & 1 & 0 \\ 0 & 0 & 0 & - 1 \\ 1 & 0 & 0 & 0 \\ 0 & 1 & 0 & 0 \\ 0 & 0 & 0 & 1 \\ 0 & 0 & 1 & 0 \\ 0 & - 1 & 0 & 0 \\ 1 & 0 & 0 & 0\end{matrix} ) , for P = 4$$

and the matrix in the appendix for P=8;

comparison means that are adapted to compare, for each symbol, two components of the vector Z̅ for the two PPM positions of this symbol, the estimated PPM position being the position corresponding to the largest amplitude component,

According to a first embodiment, the sensors are UWB antennas.

According to a second embodiment, the sensors are photodetectors.

### BRIEF DESCRIPTION OF THE DRAWINGS

Other characteristics and advantages of the invention will become clear after reading a preferred embodiment of the invention with reference to the attached figures among which:

FIG. 1 diagrammatically shows a MIMO transmission system with STBC coding known in the state of the art;

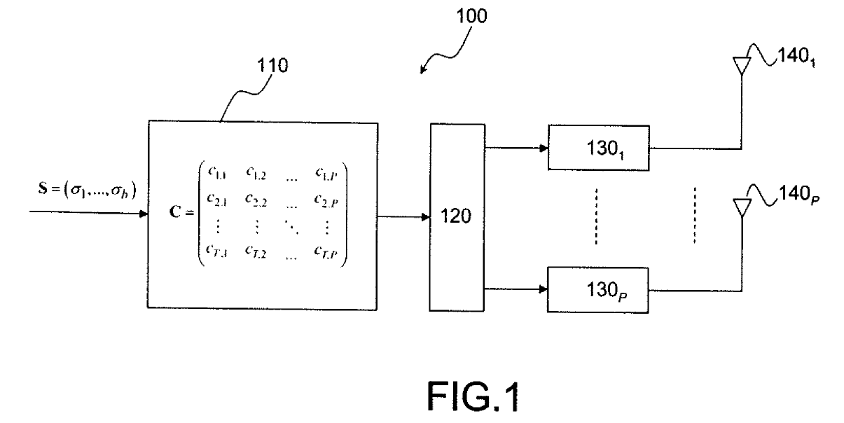

FIGS. 2A to 2C show the shapes of the TH-UWB, DS-UWB and TH-DS-UWB signals respectively;

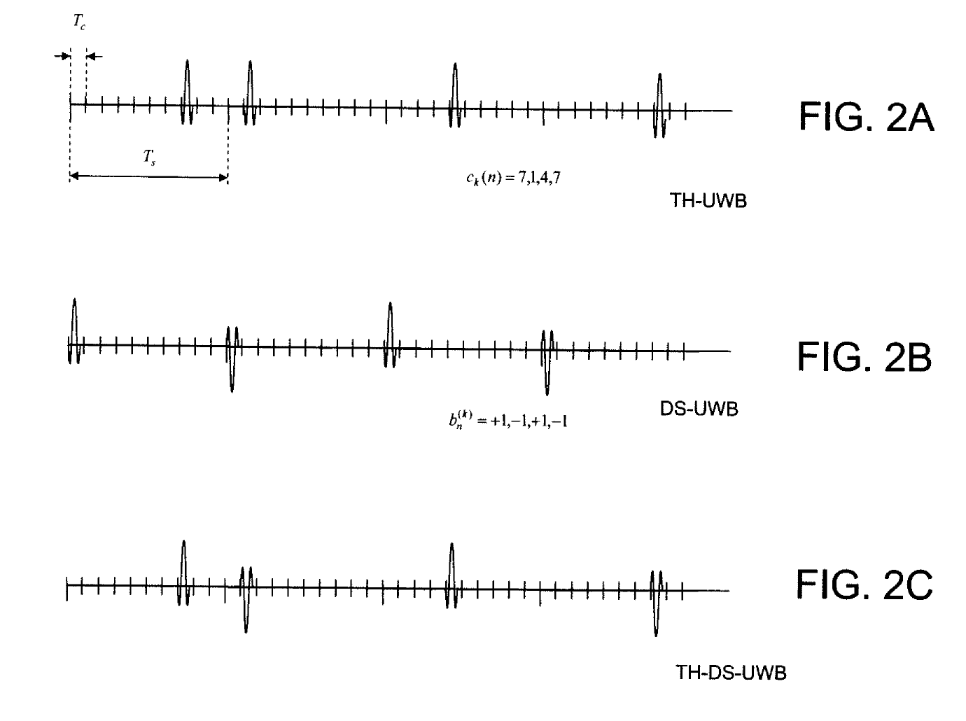

FIG. 3 diagrammatically shows a multi-antenna transmission device using a space-time coding method according to one embodiment of the invention;

FIG. 4 diagrammatically shows a reception device to decode the information symbols transmitted by the device in FIG. 3, according to one embodiment of the invention.

### DETAILED PRESENTATION OF PARTICULAR EMBODIMENTS

The basic idea of the invention is to introduce a coding diversity due to a permutation operator acting on modulation positions of information symbols.

In the following, we will consider a UWB transmission system with P=2, 4, 8 transmission antennas, or more generally, with P=2, 4, 8 radiating elements. Information symbols belong to a position modulation alphabet. As before, M will be denoted the cardinal of this alphabet.

The space-time code used by the transmission device according to the invention is defined by the following matrix,

$$for P = 2 , C = ( \begin{matrix}{σ}_{1} & {σ}_{2} \\ Ω {σ}_{2} & {σ}_{1}\end{matrix} ) \\ for P = 4 , C = ( \begin{matrix}{σ}_{1} & {σ}_{2} & {σ}_{3} & {σ}_{4} \\ Ω {σ}_{2} & {σ}_{1} & Ω {σ}_{4} & {σ}_{3} \\ Ω {σ}_{3} & {σ}_{4} & {σ}_{1} & Ω {σ}_{2} \\ Ω {σ}_{4} & Ω {σ}_{3} & {σ}_{2} & {σ}_{1}\end{matrix} ) \\ and for P = 8 , \\ C = ( \begin{matrix}{σ}_{1} & {σ}_{2} & {σ}_{3} & {σ}_{4} & {σ}_{5} & {σ}_{6} & {σ}_{7} & {σ}_{8} \\ Ω {σ}_{2} & {σ}_{1} & {σ}_{4} & Ω {σ}_{3} & {σ}_{6} & Ω {σ}_{5} & Ω {σ}_{8} & {σ}_{7} \\ Ω {σ}_{3} & Ω {σ}_{4} & {σ}_{1} & {σ}_{2} & {σ}_{7} & {σ}_{8} & Ω {σ}_{5} & Ω {σ}_{6} \\ Ω {σ}_{4} & {σ}_{3} & Ω {σ}_{2} & {σ}_{1} & {σ}_{8} & Ω {σ}_{7} & {σ}_{6} & Ω {σ}_{5} \\ Ω {σ}_{5} & Ω {σ}_{6} & Ω {σ}_{7} & Ω {σ}_{8} & {σ}_{1} & {σ}_{2} & {σ}_{3} & {σ}_{4} \\ Ω {σ}_{6} & {σ}_{5} & Ω {σ}_{8} & {σ}_{7} & Ω {σ}_{2} & {σ}_{1} & Ω {σ}_{4} & {σ}_{3} \\ Ω {σ}_{7} & {σ}_{8} & {σ}_{5} & {σ}_{6} & Ω {σ}_{3} & {σ}_{4} & {σ}_{1} & Ω {σ}_{2} \\ Ω {σ}_{8} & Ω {σ}_{7} & {σ}_{6} & {σ}_{5} & Ω {σ}_{4} & Ω {σ}_{3} & {σ}_{2} & {σ}_{1}\end{matrix} ) \qquad ( 12 )$$

where σ₁, σ₂, . . . , σ_{P} are information symbols to be transmitted, represented in the form of column vectors with dimension 2 and the components of which are all null except for a single one equal to 1, defining the modulation position. Ω is the permutation matrix 2×2, namely:

$$Ω = ( \begin{matrix}0 & 1 \\ 1 & 0\end{matrix} ) \qquad ( 13 )$$

in other words Ω is an operator that permutes the two PPM positions of a symbol. Consequently, if σ is a symbol in the PPM modulation alphabet, Ωσ will it be also.

Note that the dimensions of the matrices (12) are 2 P×P and they are formally obtained from matrices of real orthogonal codes (5) by replacing the sign change by the permutation operator Ω. This operator very advantageously introduces a space-time diversity without using a sign change, in other words without requiring an extension to the PPM modulation alphabet. It will be observed that the components of the matrix C are simply 0s and 1s and not signed values, This space-time code is suitable for modulation of an ultra-wide band signal.

The matrices C are defined except for a permutation of their rows and/or columns. Any permutation on the rows (in this case row is used to mean a row of vectors with dimension 2) and/or columns of C is a space-time code according to the invention, a permutation on the rows being equivalent to a permutation of channel use instants and a permutation on the columns being equivalent to a permutation of transmission antennas. The order of information symbols σ₁, σ₂, . . . , σ_{P} is arbitrary, it does not necessarily refer to their corresponding positions in a block of P symbols. In other words, a permutation of symbols σ₁, σ₂, . . . , σ_{P} in the matrices (12) does not modify the definition of the space-time code.

Furthermore, the matrices C each have the same number of <<1s>> in each of their columns, which results in an advantageous equal distribution of energy on the different antennas.

The space-time code C is also full rate because P information symbols are transmitted during P channel uses. Its coding gain is also higher than the known coding gains in prior art.

It can be shown that space-time codes defined by the matrices (12), and space-time codes defined by the matrices (5), have maximum diversity.

By definition, it is known that the code has maximum diversity if ΔC=C−C′ is full rank, for every pair of distinct matrices C,C′ of the code, in other words if:

$$Δ C = C = ( \begin{matrix}{a}_{1} & {a}_{2} & {a}_{3} & {a}_{4} \\ Ω {a}_{2} & {a}_{1} & Ω {a}_{4} & {a}_{3} \\ Ω {a}_{3} & {a}_{4} & {a}_{1} & Ω {a}_{2} \\ Ω {a}_{4} & Ω {a}_{3} & {a}_{2} & {a}_{1}\end{matrix} ) \\ where {a}_{p} = {σ}_{p} - {σ}_{p}^{′} for p = 1 , … , P is full rank . \qquad ( 14 )$$

By construction, the two components of vectors aₚ are either null or they have opposite signs.

The matrix ΔC can be written in developed form:

$$Δ C = ( \begin{matrix}{a}_{1 , 0} & {a}_{2 , 0} & {a}_{3 , 0} & {a}_{4 , 0} \\ {a}_{1 , 1} & {a}_{2 , 1} & {a}_{3 , 1} & {a}_{4 , 1} \\ {a}_{2 , 1} & {a}_{1 , 0} & {a}_{4 , 1} & {a}_{3 , 0} \\ {a}_{2 , 0} & {a}_{1 , 1} & {a}_{4 , 0} & {a}_{3 , 1} \\ {a}_{3 , 1} & {a}_{4 , 0} & {a}_{1 , 0} & {a}_{2 , 1} \\ {a}_{3 , 0} & {a}_{4 , 1} & {a}_{1 , 1} & {a}_{2 , 0} \\ {a}_{4 , 1} & {a}_{3 , 1} & {a}_{2 , 0} & {a}_{1 , 0} \\ {a}_{4 , 0} & {a}_{3 , 0} & {a}_{2 , 1} & {a}_{1 , 1}\end{matrix} ) \\ where \\ {a}_{l , m} = {σ}_{l , m} - {σ}_{l , m}^{′} , \\ l = 1 , 2 , 3 , 4 , m = 0 , 1 and {a}_{l , m} ∈ \{ - 1 , 0 , 1 \} \qquad ( 15 )$$

The matrix ΔC is not full rank if these two column vectors are co-linear, in other words taking account of the values of their components if these columns vectors are equal or opposite. In this case, since a_{l,0}=a_{l,1} if and only if a_{l,0}=a_{l,1}=0, it can easily be verified that the a₁ and a₂ vectors are necessarily null, in other words C=C′.

For example, in the following we will describe a transmission method when P=4, the cases P=2 and P=8 obviously being similar.

We will assume that the system uses a TH-UWB signal as defined in (6). The space-time code modulates this signal and is transmitted throughout two consecutive uses of the channel (PCU). During the first use, the p=1, . . . , 4 antennas transmit the first frames respectively:

$${s}^{P} ( t ) = {\sum }_{n = 0}^{{N}_{s} - 1} w ( t - {nT}_{s} - c ( n ) {T}_{c} - {μ}_{p} ɛ ) \qquad ( 16 )$$

During the second use of the channel, antennas p=1,3 transmit the second frames:

$${s}^{P} ( t ) = {\sum }_{n = 0}^{{N}_{s} - 1} w ( t - {nT}_{s} - c ( n ) {T}_{c} - {\overline{μ}}_{p} ɛ ) \qquad ( 17 )$$

where μ̅ₚ is the permuted position of μₚ, in other words μ̅ₚ=1 if μₚ=0 and μ̅ₚ=0 if μ̅ₚ=1, and antennas p=2,4 transmit the second frames:

$${s}^{p} ( t ) = {\sum }_{n = 0}^{{N}_{s} - 1} w ( t - {nT}_{s} - c ( n ) {T}_{c} - {μ}_{p} ɛ ) \qquad ( 18 )$$

The third and fourth frames emitted by antennas are obtained based on the same principle.

The man skilled in the art will realize that similar expressions would be obtained by using a DS-UWB signal according to expression (8), or even a DS-TH-UWB signal according to expression (10) instead of a TH-UWB signal.

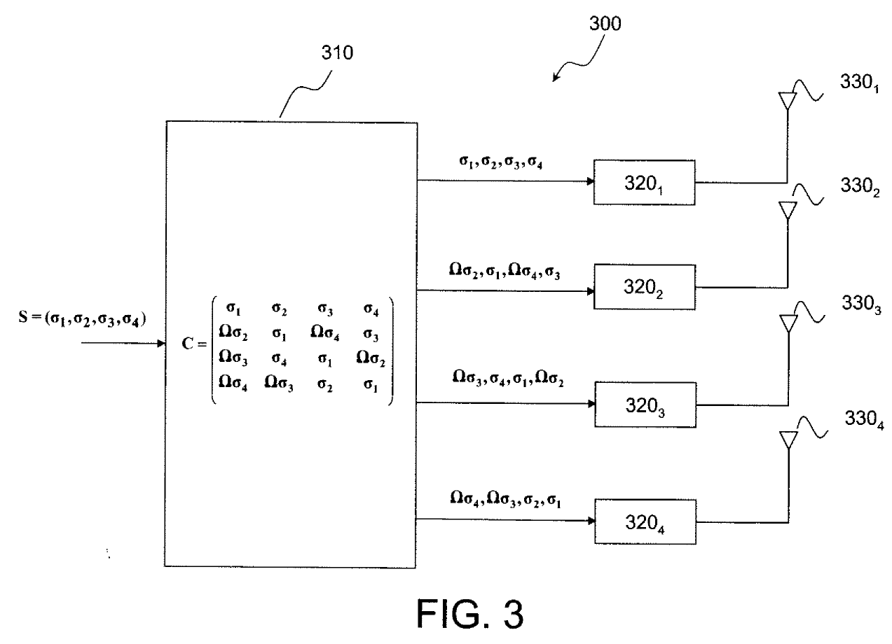

FIG. 3 shows an example of a transmission system using the space-time coding method according to the invention.

FIG. 3 shows the case in which P=4, the P=2 and P 8 cases being similar.

The system 300 receives information symbols per block S=(σ₁, σ₂, σ₃, σ₄) where σ₁, σ₂, σ₃, σ₄ are symbols of a PPM constellation with two positions. Alternately, information symbols may originate from another binary constellation, for example binary or BPSK symbols, provided that they are firstly mapped in said PPM constellation. Information symbols may be derived from one or a plurality of operations well known to those skilled in the art such as source coding, convolutional type channel coding, by block or even serial or parallel turbocoding, interlacing, etc.

A coding operation is then carried out on an information symbol block S=(σ₁, σ₂, σ₃, σ₄) in the space-time coder 310. More precisely, the module 310 calculates the coefficients of the matrix C satisfying expression (12) for P=4 or a variant obtained by permuting its rows and/or columns as described above. The four column vectors of the first row of C, representing four PPM symbols are transmitted to the UWB modulators 320₁, 320₂, 320₃, 320₄ respectively to generate the first frames, and then the four column vectors of the second row of C, to generate the second frames, and so on as far as the fourth frames.

The UWB modulator 320₁ generates the corresponding modulated UWB pulse signals from the PPM symbols σ₁, σ₂, σ₃, σ₄. Similarly, the UWB modulator 320₂ does the same from the Ωσ₂, σ₁, Ωσ₄, σ₃ vectors and the UWB modulator 320₃ with Ωσ₃, σ₄, σ₁, Ωσ₂and the modulator 320₄ with Ωσ₄, Ωσ₃, σ₂, σ₁.

Although less advantageous in the framework of this invention, the UWB pulse signals are used as a support for modulation and alternatively can be of the DS-UWB or TH-DS-UWB type. In all cases, the UWB pulse signals thus modulated are then transmitted to radiating elements 330₁ to 330₄. These radiating elements may be UWB antennas or laser diodes or LEDs, for example operating in the infrared domain associated with electro-optic modulators. The proposed transmission system can then be used in the field of wireless optical telecommunications.

UWB signals transmitted by the system shown in FIG. 3 may be received and processed by a multi-antenna receiver according to a decoding method presented below.

The decoding method according to the invention can be used to easily and robustly estimate information symbols emitted from UWB signals received by a Rake type multi-antenna receiver, much more simply than with conventional sphere decoding algorithms.

In the remainder we will assume that the transmission channel between the emitter and the receiver has a shorter pulse response than the time separation of the two modulation positions, in other words ε. This assumption will be satisfied in practice when the precaution is taken to choose ε sufficiently large to respect this constraint under statistically significant multi-path conditions. When the transmission is made optically, time spreading of the channel is generally negligible. However, it will be checked that the duration of light pulses is shorter than ε.

According to the previous assumption, a pulse of a UWB signal emitted at a first modulation position and having travelled along a first path cannot be coincident with a pulse from the same signal that travelled along a second path, in other words there will be no multipath interference between modulation positions.

We will also assume that the receiver is of the multi-antenna type and the Rake type. More precisely, each antenna 1, . . . , Q outputs the signal that it receives to a Rake receiver associated with it. Each Rake receiver has 2 L fingers, in other words 2 L filters adapted to L paths and to the two modulation positions for each path. The outputs from the 2QL fingers of the Rake receivers for the Q antennas are decision variables used by the receiver. These 2QL decision variables are observed for P intervals corresponding to the P transmitted frames. Eventually, all these observations may be represented by a matrix X with size 2QL×P representing an exhaustive summary of the signal received during the P intervals and that can be expressed in the following form:

X=HC+N (19)

where C is the 2 P×P matrix of the space-time code used by the transmission system, as given by (12) or an equivalent version by permutation of the rows and/or columns; N is a matrix with size 2QL×P representing noise samples at the output from the 2QL fingers for the P observation intervals; H is the transmission channel matrix with size 2QL×2P. We will assume that the receiver is coherent, in other words it is capable of making a channel estimate, for example by means of pilot symbols transmitted through P transmission antennas. In general, the receiver can estimate the channel matrix H by estimating the conventional multi-antenna channel.

The expression (19) can be written equivalently in vector form:

Y=vec(X)=(I_{P}\textcircled{×}H)vec(C)+vec(N) (20)

in which, for an arbitrary matrix A with size P×R, vec(A) is the vector with size PR obtained by vertically concatenating the column vectors of the matrix A, one after the other, and in which \textcircled{×} is the Kronecker product,

The vector vec(C) may be expressed as a function of the vector σ with size 2 P, obtained by vertically concatenating the vectors σ₁, σ₂, . . . , σ_{P}, namely:

vec(C)=Φ(Ω)σ (21)

where Φ(Ω) is a matrix with size 2 P²×2 P giving the linear dependence between the space-time coded symbols and information symbols, namely:

$$for P = 2 , Φ ( Ω ) = ( \begin{matrix}{I}_{2} & {O}_{2} \\ {O}_{2} & Ω \\ {O}_{2} & {I}_{2} \\ {I}_{2} & {O}_{2}\end{matrix} )$$

where O₂, I₂ and Ω are the null, unit and permutation matrices with size 2×2 respectively,

$$for P = 4 , Φ ( Ω ) = ( \begin{matrix}{I}_{2} & {O}_{2} & {O}_{2} & {O}_{2} \\ {O}_{2} & Ω & {O}_{2} & {O}_{2} \\ {O}_{2} & {O}_{2} & Ω & {O}_{2} \\ {O}_{2} & {O}_{2} & {O}_{2} & Ω \\ {O}_{2} & {I}_{2} & {O}_{2} & {O}_{2} \\ {I}_{2} & {O}_{2} & {O}_{2} & {O}_{2} \\ {O}_{2} & {O}_{2} & {O}_{2} & {I}_{2} \\ {O}_{2} & {O}_{2} & Ω & {O}_{2} \\ {O}_{2} & {O}_{2} & {I}_{2} & {O}_{2} \\ {O}_{2} & {O}_{2} & {O}_{2} & Ω \\ {I}_{2} & {O}_{2} & {O}_{2} & {O}_{2} \\ {O}_{2} & {I}_{2} & {O}_{2} & {O}_{2} \\ {O}_{2} & {O}_{2} & {O}_{2} & {I}_{2} \\ {O}_{2} & {O}_{2} & {I}_{2} & {O}_{2} \\ {O}_{2} & Ω & {O}_{2} & {O}_{2} \\ {I}_{2} & {O}_{2} & {O}_{2} & {O}_{2}\end{matrix} ) \qquad ( 22 )$$

the matrix Φ(Ω) for P=8 being obtained in the same way starting from the expression (12) for C. For example, it will be understood that the (9k+1)^{th}, k=0, . . . , 7 row vectors of Φ(Ω) will be (I₂ O₂ O₂ O₂ O₂ O₂ O₂ O₂) and the last but one will be (O₂ Ω O₂ O₂ O₂ O₂ O₂ O₂). The set of row vectors of Φ(Ω) is given in the appendix.

Considering that we have the following for an arbitrary 2-PPM symbol σₚ:

Ωσₚ=−σₚ+1₂ (23)

where 1₂=(1 1)^{T}, the Φ(Ω)σ vector may be expressed in the following manner:

Φ(Ω)σ=Φ(−I₂)σ+Γ (24)

where Φ(−I₂) is the matrix obtained by replacing Ω by −I₂ and Γ is a vector with size 2 P², constant, in other words independent of information symbols. The vector Γ is obtained from the matrix of the space-time code C by replacing the information symbols σₚ by 0₂ =(0 0)^{T} and permuted position symbols Ωσₚ by 1₂. More precisely:

Γ=vec(C⁰) (25)

with, for P=2 we have

$${C}^{0} = ( \begin{matrix}{0}_{2} & {0}_{2} \\ {1}_{2} & {0}_{2}\end{matrix} ) ,$$

and for P=4 we have

$${C}^{0} = ( \begin{matrix}{0}_{2} & {0}_{2} & {0}_{2} & {0}_{2} \\ {1}_{2} & {0}_{2} & {1}_{2} & {0}_{2} \\ {1}_{2} & {0}_{2} & {0}_{2} & {1}_{2} \\ {1}_{2} & {1}_{2} & {0}_{2} & {0}_{2}\end{matrix} ) and finally for P = 8 , \\ {C}^{0} = ( \begin{matrix}{0}_{2} & {0}_{2} & {0}_{2} & {0}_{2} & {0}_{2} & {0}_{2} & {0}_{2} & {0}_{2} \\ {1}_{2} & {0}_{2} & {0}_{2} & {1}_{2} & {0}_{2} & {1}_{2} & {1}_{2} & {0}_{2} \\ {1}_{2} & {1}_{2} & {0}_{2} & {0}_{2} & {0}_{2} & {0}_{2} & {1}_{2} & {1}_{2} \\ {1}_{2} & {1}_{2} & {1}_{2} & {0}_{2} & {0}_{2} & {1}_{2} & {0}_{2} & {1}_{2} \\ {1}_{2} & {1}_{2} & {1}_{2} & {1}_{2} & {0}_{2} & {0}_{2} & {0}_{2} & {0}_{2} \\ {1}_{2} & {0}_{2} & {1}_{2} & {0}_{2} & {1}_{2} & {0}_{2} & {1}_{2} & {0}_{2} \\ {1}_{2} & {0}_{2} & {0}_{2} & {1}_{2} & {1}_{2} & {0}_{2} & {0}_{2} & {1}_{2} \\ {1}_{2} & {1}_{2} & {0}_{2} & {0}_{2} & {1}_{2} & {1}_{2} & {0}_{2} & {0}_{2}\end{matrix} ) \qquad ( 26 )$$

Furthermore, the matrix Φ(−I₂) in equation (24) can also be expressed in the following form, making use of its blocks shape:

Φ(−I₂)=φ\textcircled{×}I₂ (27)

where φ is a matrix with size P²×P formally obtained by replacing O₂ par 0, I₂ by 1 mid Ω by −1 in the matrices (22). For example

$$for P = 2 , ϕ = ( \begin{matrix}1 & 0 \\ 0 & - 1 \\ 0 & 1 \\ 1 & 0\end{matrix} )$$

$$for P = 4 , ϕ = ( \begin{matrix}1 & 0 & & 0 & & \\ 0 & - 1 & 0 & & 0 & \\ 0 & 0 & 0 & & 0 & \\ 0 & 0 & & - 0 & & 1 \\ 0 & 1 & & 0 & & 0 \\ 1 & 0 & & 0 & & \\ 0 & 0 & 0 & & & \\ 0 & 0 - & & 1 & & 0 \\ 0 & 0 & & 1 & & 0 \\ 0 & 0 & & - 0 & & 1 \\ 1 & 0 & & 0 & & 0 \\ 0 & 1 & & 0 & & \\ 0 & 0 & & 0 & & 1 \\ 0 & 0 & & 1 & & 0 \\ 0 & - 1 & 0 & & 0 & \\ 1 & 0 & 0 & & 0 & \end{matrix} )$$

For P=8, the row vectors of φ are given in the appendix.

By combining the equations (20), (21), (24) and (27), we have:

Y=(I_{P}\textcircled{×}H)(φ\textcircled{×}I₂+Γ)+vec (N) (28)

Considering the lack of any multi-path interference between two PPM positions, the channel matrix can be characterized as follows;

H=h\textcircled{×}I₂ (29)

where h is a matrix with size QL×P. Expression (28) then becomes:

Y=(I_{P}\textcircled{×}(h\textcircled{×}I₂))((φ\textcircled{×}I₂)σ+Γ)+vec(N) (30)

If we define Z=Y−(I_{P}\textcircled{×}h\textcircled{×}I₂)Γ, we obtain the following by means of the associative property of the Kronecker product:

Z=((I_{P}\textcircled{×}h)\textcircled{×}I₂)(φ\textcircled{×}I₂)σ+vec (N) (31)

in other words:

Z=((I_{P}\textcircled{×}h)φ\textcircled{×}I₂)σ+vec(N) (32)

and if we denote h_{φ}=(I_{P}\textcircled{×}h)φ:

Z=(h_{φ}\textcircled{×}I₂)σ+vec(N) (33)

It can be shown that h_{φ} is a matrix with size PQL×P satisfying:

h_{φ}^{H}h_{φ}=αI_{P} (34)

where h_{φ}^{H} is the conjugate transpose of h_{φ} and α is a positive real number.

The result of (33) and (34) is that orthogonality of the space-time code as defined in (12) is maintained at the receiver side.

The decoding method of the space-time code, in other words the estimating of the information symbols emitted from the vector Y of decision variables, comprises the following steps:

Using the vector of decision variables Y and the channel matrix H estimated by the receiver, we calculate:

Z=Y−(I_{P}\textcircled{×}H)Γ (35)

where Γ=vec(C⁰) is a constant that only depends on the code and is therefore known to the receiver.

Using the matrix of Z and the matrix h_{φ} obtained by h_{φ}(I_{P}\textcircled{×}h)φ, where H=h\textcircled{×}I₂, we calculate the projection in a space of orthogonalized signals:

\tilde{Z}=(h_{φ}^{H}\textcircled{×}I₂)Z (36)

Finally, the p^{th} transmitted information symbol, σₚ is obtained by determining:

$${\hat{m}}_{p} = {arg max}_{m = 0 , 1} ( {\tilde{Z}}_{2 p + m - 1} ) \qquad ( 37 )$$

where Z̅₂ₚ₊ₘ₋₁ is the (2p+m−1)^{th} component of the vector Z̅ and where \hat{m}ₚ gives the PPM modulation position of the estimate \hat{σ}ₚ, in other words \hat{σ}ₚ=(δ(\hat{m}ₚ),δ(\hat{m}ₚ−1))^{T} where δ(.) is the Dirac distribution.

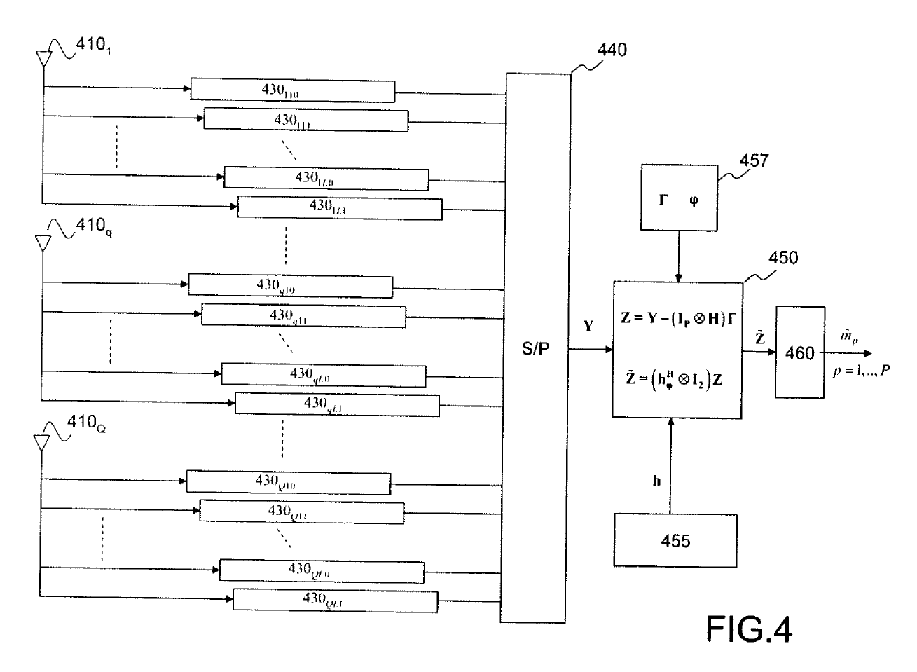

FIG. 4 shows a reception device according to one embodiment of the invention. This device is used to estimate information symbols σ₁, σ₂, . . . , σ_{P} emitted by the previously described transmission device, for example as shown in FIG. 3 for P=4.

The device comprises a plurality Q of antennas 410₁, 410₂, . . . , 410_{Q} or a plurality of photodetectors for an optical device.

Each antenna 410_{q} is connected to a Rake receiver 420_{q} having a plurality 2 L of fingers 430_{qlm} l=1, . . . , 2 L, the fingers 430_{qlm} for q=1, . . . , Q and being associated with a path l and a pulse position m. The outputs y_{qlm} of the 2QL fingers are supplied to a serial-parallel converter 440 as a vector y′ for which the components are y′_{(2l+m-1)+2ql.}=y_{qml}. The vectors y′₁, . . . , y′_{P} observed for the P transmission intervals are concatenated into a vector Y with size 2QLP by the serial parallel converter 440.

The calculation means 450 receive firstly the vector Y of the serial/parallel converter 440 and the reduced matrix h of the channel estimator 455. Furthermore, components of the vector Γ and the matrix φ are stored in a memory 457. The calculation means perform operations (35) then (37), in other words Z=Y−(I_{P}\textcircled{×}H)Γ and \tilde{Z}=(h_{φ}^{H}\textcircled{×}I₂)Z with h_{φ}=(I_{P}\textcircled{×}h)φ and H=h\textcircled{×}I₂. Finally, the 2 P components of \tilde{Z} are supplied to a comparator 460 that determines, \tilde{Z}₂ₚ₋₁ and \tilde{Z}₂ₚ for each p=1, . . . , P, to deduce therefrom

$${\hat{m}}_{p} = {arg max}_{m = 0 , 1} ( {\tilde{Z}}_{2 p + m - 1} )$$

and then the estimate \hat{σ}_{P}.

### Appendix

The 64 row vectors of the matrix φ for P=8 are given below. They are denoted v_{φ}¹ to v_{φ}⁶⁴:

v_{φ}¹=(1 0 0 0 0 0 0 0);

v_{φ}²=(0 −1 0 0 0 0 0 0);

v_{φ}³=(0 0 −1 0 0 0 0 0);

v_{φ}⁴=(0 0 0 −1 0 0 0 0);

v_{φ}⁵=(0 0 0 0 −1 0 0 0);

v_{φ}⁶=(0 0 0 0 0 −1 0 0);

v_{φ}⁷=(0 0 0 0 0 0 −1 0);

v_{φ}⁸=(0 0 0 0 0 0 0 −1);

v_{φ}⁹=(0 1 0 0 0 0 0 0);

v_{φ}¹⁰=(1 0 0 0 0 0 0 0);

v_{φ}¹¹=(0 0 0 −1 0 0 0 0);

v_{φ}¹²=(0 0 1 0 0 0 0 0);

v_{φ}¹³=(0 0 0 0 0 −1 0 0);

v_{φ}¹⁴=(0 0 0 0 1 0 0 0);

v_{φ}¹⁵=(0 0 0 0 0 0 0 1);

v_{φ}¹⁶=(0 0 0 0 0 0 −1 0);

v_{φ}¹⁷=(0 0 1 0 0 0 0 0);

v_{φ}¹⁸=(0 0 0 1 0 0 0 0);

v_{φ}¹⁹=(1 0 0 0 0 0 0 0);

v_{φ}²⁰=(0 −1 0 0 0 0 0 0);

v_{φ}²¹=(0 0 0 0 0 0 −1 0);

v_{φ}²²=(0 0 0 0 0 0 0 −1);

v_{φ}²³=(0 0 0 0 1 0 0 0);

v_{φ}²⁴=(0 0 0 0 0 1 0 0);

v_{φ}²⁵=(0 0 0 1 0 0 0 0);

v_{φ}²⁶=(0 0 −1 0 0 0 0 0);

v_{φ}²⁷=(0 1 0 0 0 0 0 0);

v_{φ}²⁸=(1 0 0 0 0 0 0 0);

v_{φ}²⁹=(0 0 0 0 0 0 0 −1);

v_{φ}³⁰=(0 0 0 0 0 0 1 0);

v_{φ}³¹=(0 0 0 0 0 −1 0 0);

v_{φ}³²=(0 0 0 0 −1 0 0 0);

v_{φ}³³=(0 0 0 0 1 0 0 0);

v_{φ}³⁴=(0 0 0 0 0 1 0 0);

v_{φ}³⁵=(0 0 0 0 0 0 1 0);

v_{φ}³⁶=(0 0 0 0 0 0 0 1);

v_{φ}³⁷=(1 0 0 0 0 0 0 0);

v_{φ}³⁸=(0 −1 0 0 0 0 0 0);

v_{φ}³⁹=(0 0 −1 0 0 0 0 0);

v_{φ}⁴⁰=(0 0 0 −1 0 0 0 0);

v_{φ}⁴¹=(0 0 0 0 0 1 0 0);

v_{φ}⁴²=(0 0 0 0 −1 0 0 0);

v_{φ}⁴³=(0 0 0 0 0 0 0 1);

v_{φ}⁴⁴=(0 0 0 0 0 0 −1 0);

v_{φ}⁴⁵=(0 1 0 0 0 0 0 0);

v_{φ}⁴⁶=(1 0 0 0 0 0 0 0);

v_{φ}⁴⁷=(0 0 0 1 0 0 0 0);

v_{φ}⁴⁸=(0 0 −1 0 0 0 0 0);

v_{φ}⁴⁹=(0 0 0 0 0 0 −1 0);

v_{φ}⁵⁰=(0 0 0 0 0 0 0 −1);

v_{φ}⁵¹=(0 0 0 0 −1 0 0 0);

v_{φ}⁵²=(0 0 0 0 0 1 0 0);

v_{φ}⁵³=(0 0 1 0 0 0 0 0);

v_{φ}⁵⁴=(0 0 0 −1 0 0 0 0);

v_{φ}⁵⁵=(1 0 0 0 0 0 0 0);

v_{φ}⁵⁶=(0 1 0 0 0 0 0 0);

v_{φ}⁵⁷=(0 0 0 0 0 0 0 1);

v_{φ}⁵⁸=(0 0 0 0 0 0 1 0);

v_{φ}⁵⁹=(0 0 0 0 0 61 0 0);

v_{φ}⁶⁰=(0 0 0 0 −1 0 0 0);

v_{φ}⁶¹=(0 0 0 1 0 0 0 0);

v_{φ}⁶²=(0 0 1 0 0 0 0 0);

v_{φ}⁶³=(0 1 0 0 0 0 0 0);

v_{φ}⁶⁴=(1 0 0 0 0 0 0 0).

1. Space-time coding method for a UWB transmission system comprising a plurality P of radiating elements where P=2, 4 or 8, said method coding a block of information symbols S=(σ₁, σ₂, . . . , σ_{P}) belonging to a 2-PPM modulation alphabet into a sequence of vectors, the components of a vector being intended to modulate the position of a UWB pulse signal for a given radiating element of said system and use of given transmission channels, each component corresponding to a PPM modulation position, characterised in that said vectors are obtained from the elements of the matrix:
$$C = ( \begin{matrix}{σ}_{1} & {σ}_{2} \\ Ω {σ}_{2} & {σ}_{1}\end{matrix} ) for P = 2 , \\ C = ( \begin{matrix}{σ}_{1} & {σ}_{2} & {σ}_{3} & {σ}_{4} \\ Ω {σ}_{2} & {σ}_{1} & Ω {σ}_{4} & {σ}_{3} \\ Ω {σ}_{3} & {σ}_{4} & {σ}_{1} & Ω {σ}_{2} \\ Ω {σ}_{4} & Ω {σ}_{3} & {σ}_{2} & {σ}_{1}\end{matrix} ) for P = 4 , \\ C = ( \begin{matrix}{σ}_{1} & {σ}_{2} & {σ}_{3} & {σ}_{4} & {σ}_{5} & {σ}_{6} & {σ}_{7} & {σ}_{8} \\ Ω {σ}_{2} & {σ}_{1} & {σ}_{4} & Ω {σ}_{3} & {σ}_{6} & Ω {σ}_{5} & Ω {σ}_{8} & {σ}_{7} \\ Ω {σ}_{3} & Ω {σ}_{4} & {σ}_{1} & {σ}_{2} & {σ}_{7} & {σ}_{8} & Ω {σ}_{5} & Ω {σ}_{6} \\ Ω {σ}_{4} & {σ}_{3} & Ω {σ}_{2} & {σ}_{1} & {σ}_{8} & Ω {σ}_{7} & {σ}_{6} & Ω {σ}_{5} \\ Ω {σ}_{5} & Ω {σ}_{6} & Ω {σ}_{7} & Ω {σ}_{8} & {σ}_{1} & {σ}_{2} & {σ}_{3} & {σ}_{4} \\ Ω {σ}_{6} & {σ}_{5} & Ω {σ}_{8} & {σ}_{7} & Ω {σ}_{2} & {σ}_{1} & Ω {σ}_{4} & {σ}_{3} \\ Ω {σ}_{7} & {σ}_{8} & {σ}_{5} & Ω {σ}_{6} & Ω {σ}_{3} & {σ}_{4} & {σ}_{1} & Ω {σ}_{2} \\ Ω {σ}_{8} & Ω {σ}_{7} & {σ}_{6} & {σ}_{5} & Ω {σ}_{4} & Ω {σ}_{3} & {σ}_{2} & {σ}_{1}\end{matrix} ) for P = 8 ,$$
each row in the matrix corresponding to one use of the transmission channel and each column of the matrix corresponding to a radiating element, the matrix C being defined except for a permutation of its rows and/or columns and Ω being a permutation of the two PPM modulation positions.

2. Method according to claim 1, characterised in that said pulse signal is a TH-UWB signal.

3. Method according to claim 1, characterised in that said pulse signal is a DS-UWB signal.

4. Method according to claim 1, characterised in that said pulse signal is a TH-DS-UWB signal.

5. UWB transmission system comprising a plurality P of radiating elements, where P=2, 4 or 8, characterised in that it also comprises:
coding means (310) to code a block of information symbols S=(σ₁, σ₂, . . . , σ_{P}) belonging to a 2-PPM modulation alphabet into a sequence of vectors, each vector being associated with a given use of the transmission channel and a given radiating element, each component of a vector corresponding to a PPM modulation position, said vectors being obtained from elements of the matrix
$$C = ( \begin{matrix}{σ}_{1} & {σ}_{2} \\ Ω {σ}_{2} & {σ}_{1}\end{matrix} ) for P = 2 , \\ C = ( \begin{matrix}{σ}_{1} & {σ}_{2} & {σ}_{3} & {σ}_{4} \\ Ω {σ}_{2} & {σ}_{1} & Ω {σ}_{4} & {σ}_{3} \\ Ω {σ}_{3} & {σ}_{4} & {σ}_{1} & Ω {σ}_{2} \\ Ω {σ}_{4} & Ω {σ}_{3} & {σ}_{2} & {σ}_{1}\end{matrix} ) for P = 4 , \\ C = ( \begin{matrix}{σ}_{1} & {σ}_{2} & {σ}_{3} & {σ}_{4} & {σ}_{5} & {σ}_{6} & {σ}_{7} & {σ}_{8} \\ Ω {σ}_{2} & {σ}_{1} & {σ}_{4} & Ω {σ}_{3} & {σ}_{6} & Ω {σ}_{5} & Ω {σ}_{8} & {σ}_{7} \\ Ω {σ}_{3} & Ω {σ}_{4} & {σ}_{1} & {σ}_{2} & {σ}_{7} & {σ}_{8} & Ω {σ}_{5} & Ω {σ}_{6} \\ Ω {σ}_{4} & {σ}_{3} & Ω {σ}_{2} & {σ}_{1} & {σ}_{8} & Ω {σ}_{7} & {σ}_{6} & Ω {σ}_{5} \\ Ω {σ}_{5} & Ω {σ}_{6} & Ω {σ}_{7} & Ω {σ}_{8} & {σ}_{1} & {σ}_{2} & {σ}_{3} & {σ}_{4} \\ Ω {σ}_{6} & {σ}_{5} & Ω {σ}_{8} & {σ}_{7} & Ω {σ}_{2} & {σ}_{1} & Ω {σ}_{4} & {σ}_{3} \\ Ω {σ}_{7} & {σ}_{8} & {σ}_{5} & Ω {σ}_{6} & Ω {σ}_{3} & {σ}_{4} & {σ}_{1} & Ω {σ}_{2} \\ Ω {σ}_{8} & Ω {σ}_{7} & {σ}_{6} & {σ}_{5} & Ω {σ}_{4} & Ω {σ}_{3} & {σ}_{2} & {σ}_{1}\end{matrix} ) for P = 8 ,$$
one row of the matrix corresponding to one use of the transmission channel and one column of the matrix corresponding to one radiating element, the matrix C being defined within one permutation of its rows and/or columns and Ω being a permutation of the two PPM modulation positions;
a plurality of modulators (320₁, 320₂, . . . , 320_{P}) to modulate the position of a UWB pulse signal, each modulator being associated with a radiating element and modulating the position of said signal, during use of the transmission channel, by means of components of the vector associated with said radiating element and said use of the channel;
each radiating element being adapted to emit the signal thus modulated by said associated modulator.

6. Transmission system according to claim 5, characterised in that radiating elements are UWB antennas.

7. Transmission system according to claim 5, characterised in that radiating elements are laser diodes or light emitting diodes.

8. Space-time decoding method for a UWB reception system with Q sensors, designed to estimate information symbols transmitted by the transmission system according to claim 5, characterised in that it comprises:
a step to obtain 2QL decision variables associated with 2QL reception channels, each reception channel being related to a sensor, a propagation path between the transmission and reception systems, and a modulation position of the 2-PPM modulation alphabet, said obtaining step being repeated for P consecutive uses of the transmission channel, to provide a vector Y with size 2QLP, for which the components are the 2QL decision variables obtained for said P uses;
a step to calculate the vector Z=Y−(I_{P}\textcircled{×}H)Γ where I_{P} is the unit matrix with size P×P, H is the matrix representative of the transmission channel, Γ is a constant vector representative of the code and \textcircled{×} is the Kronecker product;
a step to calculate the \tilde{Z}=(h_{φ}^{H}\textcircled{×}I₂)Z vector, where h_{φ}=(I_{P}\textcircled{×}h)φ, and where I₂ is the unit matrix with size 2×2, h is a reduced channel matrix such that H=h\textcircled{×}I₂ and φ is the matrix
$$ϕ = ( \begin{matrix}1 & 0 \\ 0 & - 1 \\ 0 & 1 \\ 1 & 0\end{matrix} ) for P = 2 , \\ ϕ = ( \begin{matrix}1 & 0 & 0 & 0 \\ 0 & - 1 & 0 & 0 \\ 0 & 0 & 0 & 0 \\ 0 & 0 & 0 & - 1 \\ 0 & 1 & 0 & 0 \\ 1 & 0 & 0 & 0 \\ 0 & 0 & 0 & 1 \\ 0 & 0 & - 1 & 0 \\ 0 & 0 & 1 & 0 \\ 0 & 0 & 0 & - 1 \\ 1 & 0 & 0 & 0 \\ 0 & 1 & 0 & 0 \\ 0 & 0 & 0 & 1 \\ 0 & 0 & 1 & 0 \\ 0 & - 1 & 0 & 0 \\ 1 & 0 & 0 & 0\end{matrix} ) , for P = 4$$
and the matrix in the appendix for P=8;
a step, for each symbol, to compare the components of the vector \tilde{Z} applicable to the two PPM positions of this symbol, the estimated PPM position being the position corresponding to the largest amplitude component.

9. UWV reception system comprising a plurality Q of sensors and for each sensor, an associated Rake receiver, characterised in that each Rake receiver comprises a plurality 2 L of fingers, each finger corresponding to a propagation path and to a modulation position of the 2-PPM modulation alphabet, the system also comprising:
serial-parallel conversion means to form a vector Y with size 2QLP, for which the components are the 2QL outputs from the Rake receiver fingers, for P consecutive uses of the transmission channel;
calculation means, firstly to calculate a vector Z=Y−(I_{P}\textcircled{×}H)Γ where I_{P} is the unit matrix with size P×P, H is a matrix representative of the transmission channel, Γ is a constant vector representative of the code and \textcircled{×} is the Kronecker product, then a vector \tilde{Z}=(h_{φ}^{H}\textcircled{×}I₂)Z where h_{φ}=(I_{P}\textcircled{×}h)φ, and where I₂ is the unit matrix with size 2×2, h is a reduced channel matrix such that H=h\textcircled{×}I₂ and φ is the matrix:
$$ϕ = ( \begin{matrix}1 & 0 \\ 0 & - 1 \\ 0 & 1 \\ 1 & 0\end{matrix} ) for P = 2 , \\ ϕ = ( \begin{matrix}1 & 0 & 0 & 0 \\ 0 & - 1 & 0 & 0 \\ 0 & 0 & 0 & 0 \\ 0 & 0 & 0 & - 1 \\ 0 & 1 & 0 & 0 \\ 1 & 0 & 0 & 0 \\ 0 & 0 & 0 & 1 \\ 0 & 0 & - 1 & 0 \\ 0 & 0 & 1 & 0 \\ 0 & 0 & 0 & - 1 \\ 1 & 0 & 0 & 0 \\ 0 & 1 & 0 & 0 \\ 0 & 0 & 0 & 1 \\ 0 & 0 & 1 & 0 \\ 0 & - 1 & 0 & 0 \\ 1 & 0 & 0 & 0\end{matrix} ) , for P = 4$$
and the matrix in the appendix for P=8;
means of comparing the two components of the vector Z̅ applicable to the two PPM positions of each symbol, the estimated PPM position being the position corresponding to the largest amplitude component.

10. Reception system according to claim 9, characterised in that the sensors are UWB antennas.

11. Reception system according to claim 9, characterised in that the sensors are photodetectors.
